(19) United States
(12) Patent Application Publication
(10) Pub. No.: US 2026/0271493 A1
(43) Pub. Date: Sep. 10, 2026

(54) LIGHT-EMITTING ELEMENT, DISPLAY DEVICE, AND PRODUCTION METHOD FOR LIGHT-EMITTING ELEMENT

(71) Applicant: Sharp Display Technology Corporation, Kameyama City, Mie (JP)

(72) Inventor: YOSHIHIRO UETA, Sakai City, Osaka (JP)

(21) Appl. No.: 19/120,413

(22) PCT Filed: Oct. 19, 2022
(86) PCT No.: PCT/JP2022/038899

§ 371 Date: Apr. 11, 2025

(51) Int. Cl. H10K 50/115

(52) U.S. Cl. CPC H10K 50/115

(57) ABSTRACT

A light-emitting element includes a quantum dot layer positioned between an anode and a cathode and including a first quantum dot and a second quantum dot, and the quantum dot layer fills a space between the first quantum dot and the second quantum dot and at least a part of a portion of an inorganic matrix material in contact with the first quantum dot is amorphous.

### TECHNICAL FIELD

The disclosure relates to a light-emitting element, a display device, and a light-emitting element manufacturing method.

### BACKGROUND ART

PTL 1 relates to a manufacturing method for a quantum dot-inorganic matrix composite, and the manufacturing method includes manufacturing an inorganic matrix precursor solution including a quantum dot precursor, and then spin-coating the matrix precursor solution on a substrate and heat-treating the spin-coated matrix precursor solution to obtain a quantum dot-inorganic matrix composite.

### Citation List

### Patent Literature

PTL 1: JP-2009-263621 A (published on Nov. 12, 2009)

### SUMMARY OF INVENTION

### Technical Problem

There is a demand for improving External Quantum Efficiency (EQE) of a light-emitting element.

### Solution to Problem

According to an aspect of the disclosure, there is provided a light-emitting element including an anode and a cathode, and a quantum dot layer positioned between the anode and the cathode, the quantum dot layer including a first quantum dot and a second quantum dot, wherein the quantum dot layer includes an inorganic matrix material filling a space between the first quantum dot and the second quantum dot, and a portion of the inorganic matrix material in contact with the first quantum dot is at least partially amorphous.

According to an aspect of the disclosure, there is provided a light-emitting element manufacturing method including forming a coating film including a first quantum dot, a second quantum dot, a precursor of a group II-VI compound, and a solvent, and heating the coating firm, thus causing the precursor to be modified into the group II-VI compound, and then cooling the coating film at a rate equal to or more than 100 degrees Celsius/second.

### Advantageous Effects of Invention

According to one aspect of the disclosure, EQE of the light-emitting element can be improved.

### BRIEF DESCRIPTION OF DRAWINGS

FIG. 1 is a cross-sectional view illustrating an example of a light-emitting element according to an embodiment of the disclosure.

FIG. 2 is a cross-sectional view illustrating an example of a quantum dot layer illustrated in FIG. 1.

FIG. 3 is a cross-sectional view illustrating an example of a region between quantum dots illustrated in FIG. 1.

FIG. 4 is a view illustrating an example of an electron beam diffraction image obtained from a sample in which a crystalline portion and an amorphous portion are mixed in a continuous film.

FIG. 5 is a view illustrating an example of an electron beam diffraction image obtained from a sample in which a crystalline portion and an amorphous portion are mixed in a continuous film.

FIG. 6 is a view illustrating an example of an electron beam diffraction image obtained from a sample in which the crystalline portion and the amorphous portion are mixed in the continuous film.

FIG. 7 is a flowchart illustrating an example of a manufacturing method for the light-emitting element illustrated in FIG. 1.

FIG. 8 is a flowchart illustrating another example of the manufacturing method for the light-emitting element illustrated in FIG. 1.

FIG. 9 is a diagram illustrating an example of a case where an inorganic matrix contains a group II-VI compound in forming the quantum dot layer illustrated in FIG. 1.

FIG. 10 is a cross-sectional view illustrating a quantum dot layer of Comparative Example.

FIG. 11 is a cross-sectional view illustrating a quantum dot layer of Comparative Example.

FIG. 12 is a current density-EQE graph of light-emitting elements of Example and Comparative Example.

FIG. 13 is a voltage-EQE graph of the light-emitting elements of Example and Comparative Example.

FIG. 14 is a cross-sectional view illustrating an example of a quantum dot layer according to an embodiment of the disclosure.

FIG. 15 is a cross-sectional view illustrating an example of a quantum dot layer according to an embodiment of the disclosure.

FIG. 16 is a cross-sectional view illustrating an example of a quantum dot layer according to an embodiment of the disclosure.

FIG. 17 is a schematic view illustrating an example of a display device according to an embodiment of the disclosure.

### DESCRIPTION OF EMBODIMENTS

### First Embodiment

### Configuration of Light-Emitting Element

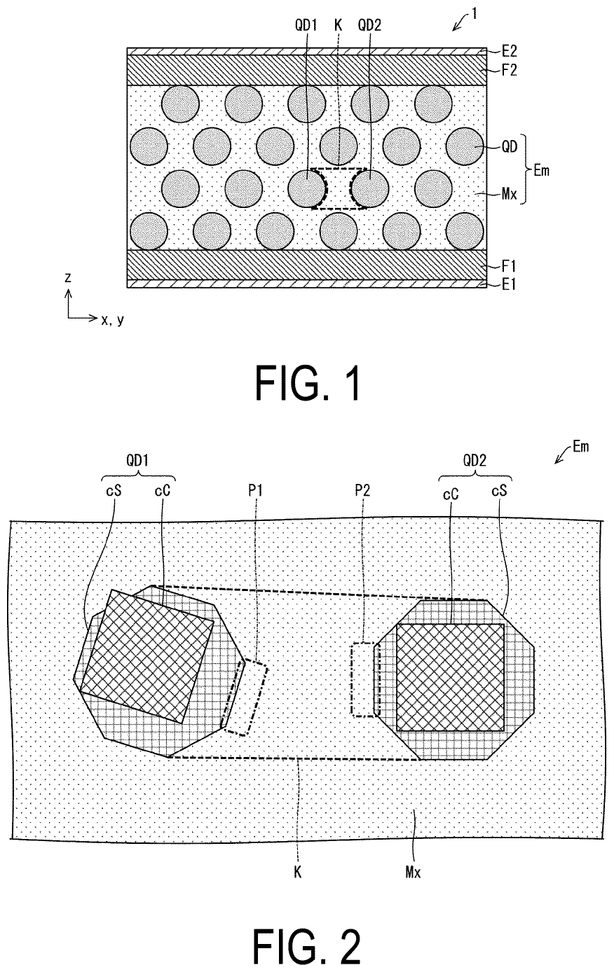

FIG. 1 is a cross-sectional view illustrating an example of a light-emitting element 1 according to a first embodiment of the disclosure. As illustrated in FIG. 1, the light-emitting element 1 includes an anode E1 and a cathode E2 facing each other, and a quantum dot layer Em positioned between the anode E1 and the cathode E2. At least one of the anode E1 or the cathode E2 is a transparent electrode. The quantum dot layer Em is a light-emitting layer. The quantum dot layer Em includes a plurality of quantum dots QD including a first quantum dot QD1 and a second quantum dot QD2, and an inorganic matrix material Mx filling a space between the first quantum dot QD1 and the second quantum dot QD2.

The light-emitting element 1 may further include a charge function layer F1 between the anode E1 and the quantum dot layer Em, and/or may further include a charge function layer F2 between the cathode E2 and the quantum dot layer Em. The charge function layers F1 and F2 may include, for example, one or more among a hole injection layer, a hole transport layer, an electron blocking layer, a hole blocking layer, an electron transport layer, and an electron injection layer. The light-emitting element 1 may be a tandem type including a plurality of quantum dot layers Em and a carrier generation layer.

A layer thickness of the quantum dot layer Em may be from 10 to 50 [nm]. A quantum dot density in the quantum dot layer Em may be from 1×10¹⁷ to 6×10¹⁷ [cm⁻³]. An average particle diameter of the plurality of quantum dots QD may be from 5 to 50 [nm].

FIG. 2 is a cross-sectional view illustrating an example of the quantum dot layer illustrated in FIG. 1. As illustrated in FIG. 2, the inorganic matrix material Mx includes a portion being in contact with the first quantum dot QD1 and a portion being in contact with the second quantum dot QD2. At least a part of the portion of the inorganic matrix material Mx in contact with the first quantum dot QD1, for example, a portion P1, is amorphous. At least a part of the portion of the inorganic matrix material Mx in contact with the second quantum dot QD2, for example, a portion P2, may be amorphous. The inorganic matrix material Mx may be amorphous in a region K.

The inorganic matrix material Mx may be mostly or entirely amorphous. For example, in cross-sectional observation, the amorphous portion of the inorganic matrix material Mx may occupy 50% or more, or 70% or more of the entire cross-sectional area of the inorganic matrix material Mx. Moreover, most or all of a portion of the inorganic matrix material Mx in contact with the quantum dot QD may be amorphous. For example, in the cross-sectional observation, a length of the amorphous portion of the inorganic matrix material Mx in contact with the quantum dot QD may account for 50% or more, or 88% or more of an outer peripheral length of the quantum dot. For example, in the cross-sectional observation, the entire portion where the inorganic matrix material Mx is in contact with the first quantum dot QD1 may be amorphous, and the entire portion where the inorganic matrix material Mx is in contact with the second quantum dot QD2 may be amorphous. In particular, it is preferable that the portions of the inorganic matrix material Mx in contact with the quantum dots QD be entirely amorphous.

### Quantum Dot

Each of the first quantum dot QD1 and the second quantum dot QD2 according to the first embodiment has a core-shell structure including a core cC that is crystalline and a shell cS that is crystalline. The shell cS may be provided on a surface of the core cC. The shell cS may be partially formed at the surface of the core cC like the first quantum dot QD1 or may completely cover the core cC like the second quantum dot QD2. The shell cS that is crystalline may be constituted by a plurality of layers, that is, the quantum dot QD may have a multi-shell structure.

Note that none of FIG. 1, FIG. 2 and the following figures limit the shapes and sizes of the quantum dot QD, the core cC that is crystalline, and the shell cS that is crystalline. None of the figures limit the relationship between the core cC and the shell cS. None of the figures limit crystal forms of the core cC and the shell cS.

### Inorganic Matrix Material

The inorganic matrix material Mx means a member that includes and holds other objects, and can be referred to as a base material, a matrix, or a filler. The inorganic matrix material Mx may be solid at room temperature. The inorganic matrix material Mx may be a member that includes and holds the plurality of quantum dots QD. The inorganic matrix material Mx may be a constituent component of the quantum dot layer Em including the plurality of quantum dots QD.

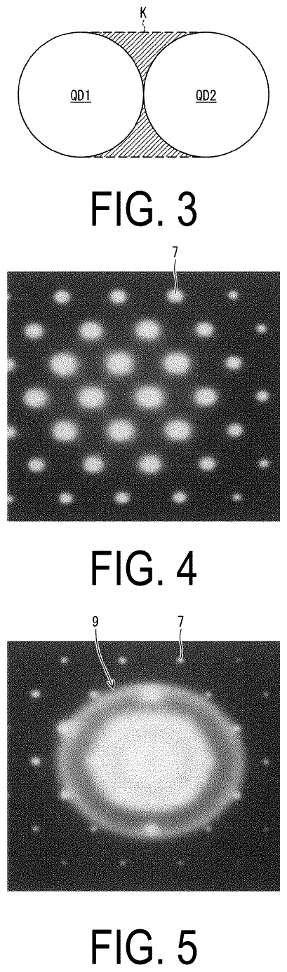

FIG. 3 is a cross-sectional view illustrating an example of a region between quantum dots illustrated in FIG. 1. The inorganic matrix material Mx may be filled in the quantum dot layer Em. As illustrated in FIG. 1 to FIG. 3, the inorganic matrix material Mx may fill the region (space) K between the first and second quantum dots QD1 and QD2. As illustrated in FIG. 1 and FIG. 3, the region K is a region surrounded by two straight lines (external common tangents) circumscribing the outer peripheries of the first and second quantum dots QD1 and QD2 and the outer peripheries of the first and second quantum dots QD1 and QD2 facing each other in a cross-sectional view. As illustrated in FIG. 3, even when the first quantum dot QD1 is close to the second quantum dot QD2, the region K can exist.

The fact that the inorganic matrix material Mx fills the spaces between the plurality of quantum dots QD means that the matrix material Mx fills the region K between two quantum dots QD adjacent to each other as described above, and it is sufficient to confirm the fact. In other words, as long as the inorganic matrix material Mx at least fills the region K between the two adjacent quantum dots QD, a desired effect of the inorganic matrix material Mx can be achieved. Thus, the fact that the inorganic matrix material Mx fills the spaces between the plurality of quantum dots QD does not necessarily mean that it is confirmed that the inorganic matrix material Mx fills the spaces between all (more than two) quantum dots QD in a certain range.

As illustrated in FIG. 1, the inorganic matrix material Mx may fill a region (space) other than the plurality of quantum dots QD including the first and second quantum dots QD1 and QD2 in the quantum dot layer Em. The inorganic matrix material Mx may fill a region (space) other than a quantum dot group in the quantum dot layer Em. Note that three or more quantum dots QD including the first and second quantum dots QD1 and QD2 are collectively referred to as the quantum dot group.

Outer edges (an upper surface and a lower surface) of the quantum dot layer Em may be covered with the inorganic matrix material Mx. Alternatively, a portion of the inorganic matrix material Mx may be configured to exist from the outer edges of the quantum dot layer Em, positioning the quantum dot group away from the outer edges. The outer edges of the quantum dot layer Em need not be formed only by the inorganic matrix material Mx, and one or some among the quantum dot group may be exposed from the inorganic matrix material Mx. The inorganic matrix material Mx may indicate a portion of the quantum dot layer Em excluding the quantum dot group.

The inorganic matrix material Mx may enclose the first and second quantum dots QD1 and QD2. The inorganic matrix material Mx may enclose a quantum dot group including the first and second quantum dots QD1 and QD2. The inorganic matrix material Mx may be formed so as to partially or completely fill a space K formed between the first and second quantum dots QD1 and QD2. A void may be present in the quantum dot layer Em. The quantum dot layer Em may include the quantum dot group including the first and second quantum dots QD1 and QD2, and the inorganic matrix material Mx partially or completely may fill a region other than the quantum dot group. The first and second quantum dots QD1 and QD2 may be embedded in the inorganic matrix material Mx at an interval.

The inorganic matrix material Mx may include a continuous film having an area equal to or larger than 1000 nm² along a plane direction orthogonal to a layer thickness direction of the quantum dot layer Em. The continuous film means a film not partitioned by a material other than a material constituting the continuous film in one plane. The continuous film may be in the form of an integrated film connected without interruption by chemical bonding of the material constituting the inorganic matrix material Mx.

The inorganic matrix material Mx may be the same material as the material of the shells of the quantum dot group including the first and second quantum dots QD1 and QD2. In this case, an average distance between the cores adjacent to each other (core-to-core distance) may be equal to or larger than 3 nm or may be equal to or larger than 5 nm. Alternatively, the average distance between the cores adjacent to each other may be 0.5 times or more the average core diameter. The core-to-core distance is an average of distances between adjacent cores in a space including 20 cores. The core-to-core distance may be kept wider than the distance when the shells are in contact with each other. The average core diameter is obtained by averaging the core diameters of the 20 cores in cross-sectional observation in the space including the 20 cores. The core diameter can be the diameter of a circle having the same area as the core area in the cross-sectional observation.

A concentration of the inorganic matrix material Mx in the quantum dot layer Em is, for example, an area percentage occupied by the inorganic matrix material Mx in a cross section of the quantum dot layer Em. This concentration may be 10% or more and 90% or less, or 30% or more and 70% or less in the cross-sectional observation. The concentration may be measured, for example, from an area percentage in image processing in the cross-sectional observation. When the quantum dot group has a core-shell structure, the concentration of the shells may be 1% or more and 50% or less.

The quantum dot layer Em may be constituted by the quantum dot group including the first and second quantum dots QD1 and QD2, and the inorganic matrix material Mx.

Regarding the structure of the inorganic matrix material Mx, the configuration described above need not be observed over the entirety of the quantum dot layer Em as long as the configuration described above is understood by observing the quantum dot layer Em across a width of about 100 nm in the cross-sectional observation unless otherwise noted or unless a contradiction arises. The inorganic matrix material Mx may contain a substance different from the main material (for example, an inorganic substance such as an inorganic semiconductor), for example, as an additive. The observation result of a portion of the quantum dot layer Em may be applied to the entire quantum dot layer Em.

In the disclosure, “the same material” and terms similar to “the same material” (for example, “the same substance” and the like) mean materials having the same constituent element and the same composition ratio thereof. In addition, “a different material” and terms similar to “a different material” (for example, “a different substance” and the like) mean materials having different constituent elements or materials having the same constituent element but different composition ratios.

### Electron Beam Diffraction Image

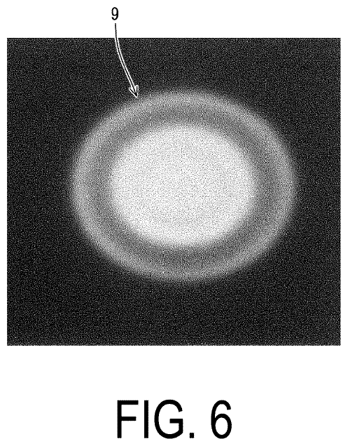

Each of FIG. 4 to FIG. 6 is a view illustrating an example of an electron beam diffraction image obtained from a sample in which the crystalline portion and the amorphous portion are mixed in the continuous film. FIG. 4 illustrates an electron beam diffraction image obtained by electron beam diffraction at the crystalline portion of the sample and includes a bright spot group pattern. FIG. 5 illustrates an electron beam diffraction image obtained by electron beam diffraction at a boundary portion between the crystalline portion and the amorphous portion of the sample, and includes the bright spot group pattern and a halo pattern 9 in an overlapping manner. FIG. 6 illustrates an electron beam diffraction image obtained by electron beam diffraction at the amorphous portion of the sample, and includes the halo pattern 9. The bright spot group pattern includes a plurality of bright spots 7 regularly arrayed, and the halo pattern 9 includes a concentric bright-dark pattern. Note that in FIG. 4 and FIG. 5, as the bright spot group pattern of the electron beam diffraction image obtained by electron beam diffraction at the crystalline portion, a six fold rotational symmetry pattern caused by a hexagonal crystal is illustrated, but an electron beam diffraction image to be obtained is not limited thereto. In FIG. 5 and FIG. 6, the concentric bright-dark pattern in which a bright portion and a dark portion are repeated is illustrated as the halo pattern 9, but the halo pattern 9 is not limited thereto. Additionally, the boundary portion between the crystalline portion and the amorphous portion includes a boundary between the crystalline portion and the amorphous portion and the vicinity of the boundary.

Note that in this specification, an electron beam diffraction image of a certain portion is obtained by electron beam irradiation with a field of view limited only to the portion. To be specific, in this specification, the electron beam diffraction image of the portion is obtained by limiting an irradiation field so as to irradiate only the portion with the electron beam, limiting a detection field so as to detect only the electron beam having passed through the portion, or limiting both the irradiation field and the detection field.

Thus, the light-emitting element 1 according to the disclosure can also be expressed as follows. The light-emitting element 1 includes the anode E1 and the cathode E2, and the quantum dot layer Em located between the anode E1 and the cathode E2 and including the first quantum dot QD1 and the second quantum dot QD2. The quantum dot layer Em includes the inorganic matrix material Mx filling the space between the first quantum dot QD1 and the second quantum dot QD2, and an electron beam diffraction image of the inorganic matrix material Mx between the first quantum dot QD1 and the second quantum dot QD2 includes a halo pattern 9.

As described above, each of the core cC and the shell cS of the first quantum dot QD1 is crystalline. Thus, an electron beam diffraction image of a boundary portion between the shell cS of the first quantum dot QD1 and the inorganic matrix material Mx includes the bright spot group pattern and the halo pattern 9 in an overlapping manner. In addition, when the core cC of the first quantum dot QD1 is in contact with the inorganic matrix material Mx, an electron beam diffraction image of a boundary portion between the core cC of the first quantum dot QD1 and the inorganic matrix material Mx includes the bright spot group pattern and the halo pattern 9 in an overlapping manner.

The inorganic matrix material Mx may include a portion that is monocrystalline or polycrystalline. Thus, an electron beam diffraction image of any part of the inorganic matrix material Mx may include a bright spot group pattern. Alternatively, the entire inorganic matrix material Mx may be amorphous.

Note that whether the target portion is crystalline or amorphous may be determined by using a visual resource other than the electron beam diffraction image. For example, whether an atomic arrangement is periodic or irregular may be determined from a photograph taken by using a high-resolution Transmission Electron Microscope (TEM). In the photograph, a portion representing a periodic atomic arrangement is crystalline, and a portion representing an irregular atomic arrangement is amorphous.

### Material

The shell cS of the first quantum dot QD1 and the inorganic matrix material Mx may be made of the same material. Alternatively, the shell cS of the first quantum dot QD1 and the inorganic matrix material Mx may be made of different materials. A band gap of the inorganic matrix material Mx may be larger than a band gap of the shell cS of the first quantum dot QD1, and may be larger than a band gap of the core cC of the first quantum dot QD1. Similarly, the shell cS of the second quantum dot QD2 and the inorganic matrix material Mx may be made of the same material or different materials.

The inorganic matrix material Mx may include one or more of a group II-VI compound, a group III-V compound, a metal oxide, and a metal sulfide as a material. The inorganic matrix material Mx may contain a metal chalcogenide. The inorganic matrix material Mx may contain, for example, at least one of zinc sulfide, zinc oxide, and magnesium oxide. The inorganic matrix material Mx may contain, for example, at least one of a selenium (Se) element and a tellurium (Te) element. The inorganic matrix material Mx may contain a mixed crystal containing a plurality of compounds.

In the disclosure, the numbering of groups of elements by using Roman numerals is numbering based on the old International Union of Pure and Applied Chemistry (IUPAC) system, and the numbering of groups of elements by using Arabic numerals is numbering based on the new IUPAC system. Note that the group II-VI compound refers to a compound constituted by a group II element and a group VI element, and the group III-V compound refers to a compound constituted by a group III element and a group V element. Composition percentages of the materials constituting the quantum dot QD and the inorganic matrix material Mx may be different from the stoichiometric composition (stoichiometry).

### Light-Emitting Element Manufacturing Method

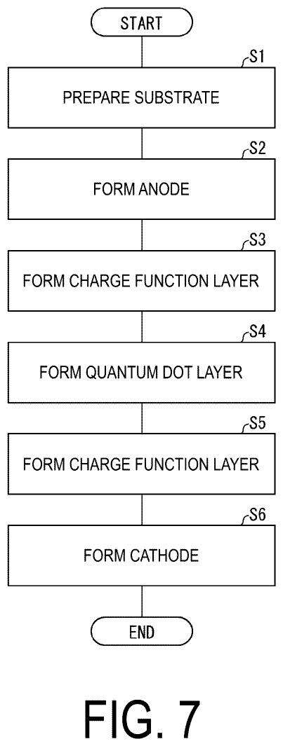

FIG. 7 is a flowchart illustrating an example of a manufacturing method for light-emitting element illustrated in FIG. 1. As illustrated in FIG. 7, the light-emitting element manufacturing method may sequentially include preparing a substrate (step S1), forming an anode E1 on the substrate (step S2), forming a charge function layer F1 on the anode E1 (step S3), forming a quantum dot layer Em on the charge function layer F1 (step S4), forming a charge function layer F2 on the quantum dot layer Em (step S5), and forming a cathode E2 on the charge function layer F2 (step S6).

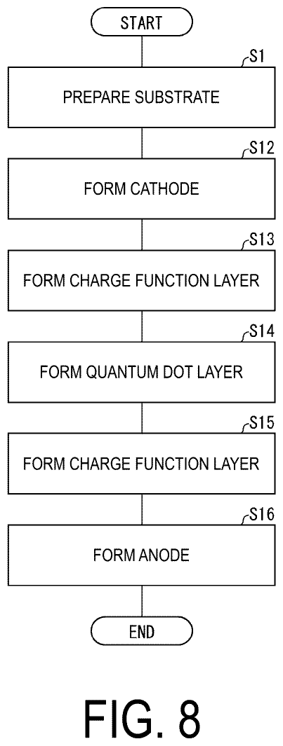

FIG. 8 is a flowchart illustrating another example of the manufacturing method for the light-emitting element illustrated in FIG. 1. As illustrated in FIG. 8, the light-emitting element manufacturing method may sequentially include preparing a substrate (step S1), forming a cathode E2 on the substrate (step S12), forming a charge function layer F2 on the cathode E2 (step S13), forming a quantum dot layer Em on the charge function layer F2 (step S14), forming a charge function layer F1 on the quantum dot layer Em (step S15), and forming an anode E1 on the charge function layer F1 (step S16).

### Manufacturing Method for Quantum Dot Layer

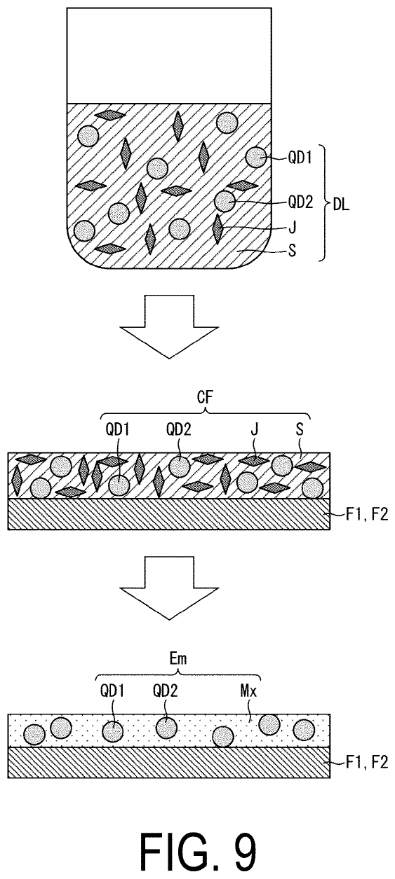

FIG. 9 is a diagram illustrating an example of a case where the inorganic matrix contains a group II-VI compound in the forming of the quantum dot layer illustrated in FIG. 1. First, a plurality of quantum dots QD including the first quantum dot QD1 and the second quantum dot QD2 are synthesized. The quantum dot QD may be synthesized by any method, and a known method may be used. Next, as illustrated in the upper part of FIG. 9, the quantum dots QD and a precursor J of the group II-VI compound are dispersed in a solvent S to obtain a quantum dot dispersion DL. The quantum dot dispersion DL includes the first quantum dot QD1, the second quantum dot QD2, the precursor J, and the solvent S.

Next, as illustrated in the middle part of FIG. 9, the quantum dot dispersion DL is applied on the charge function layer F1 or the charge function layer F2 to form a coating film CF. The coating film CF includes the first quantum dot QD1, the second quantum dot QD2, the precursor J, and the solvent S.

Next, as illustrated in the lower part of FIG. 9, the coating film CF is heated and cooled to form the quantum dot layer Em. In this step, first, the coating film CF is heated so as to remove the solvent S from the coating film CF. Subsequently or simultaneously, the coating film CF is heated such that the precursor J in the coating film CF is modified into a group II-VI compound. Then, the coating film CF is rapidly cooled, for example, at a rate of 100 degrees Celsius/second or more. This rapid cooling solidifies the group II-VI compound faster than an average time required for the constituent elements of the group II-VI compound to move to intrinsic crystal lattice points of the group II-VI compound. Thus, most or all of the constituent elements are not positioned at the intrinsic crystal lattice points. That is, the group II-VI compound becomes amorphous, and the inorganic matrix material Mx that is amorphous is formed. In addition, the coating film CF may be cooled to a sufficiently low temperature, for example, 40 degrees Celsius or less so that the constituent elements do not obtain thermal energy necessary for the constituent elements to move to the crystal lattice points after the cooling. The sufficient cooling maintains the disordered amorphous state without transitioning to an ordered crystalline state. During and/or after the heating, a heat retention period in which the temperature of the coating film CF is maintained may be provided for the purpose of securing a reaction time for the modification of the precursor J or the like.

The manufacturing method for the quantum dot layer Em according to the disclosure is not limited to the above-described method. The inorganic matrix material Mx may contain a material or impurities other than the group II-VI compound, and the inorganic matrix material Mx may be amorphized by a method other than the rapid cooling.

In addition to the rapid cooling, for example, the maximum heating temperature of the coating film CF may be made lower than that when the inorganic matrix material is crystallized. By low-temperature heating, the constituent elements cannot obtain sufficient thermal energy to move to the crystal lattice points. When the inorganic matrix material contains the group II-VI compound, the precursor J can be modified in the entire coating film CF and the inorganic matrix material Mx can be substantially uniformly amorphized by lowering the maximum heating temperature by about 50 degrees Celsius and prolonging the reaction time by about 50% as compared with the case of crystallization.

### Comparison With Comparative Example 1

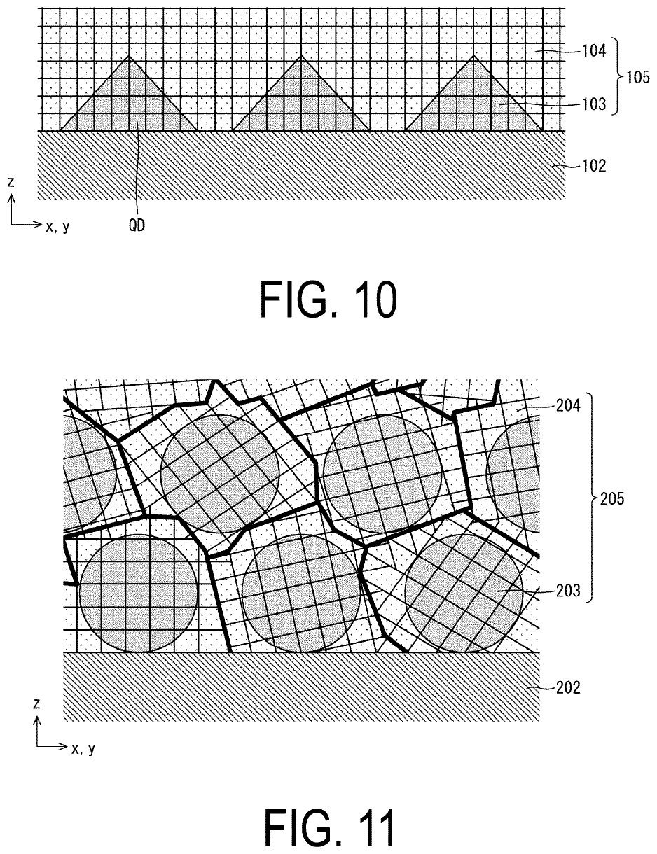

FIG. 10 is a cross-sectional view illustrating a quantum dot layer of Comparative Example 1. In Comparative Example 1, as illustrated in FIG. 10, a quantum dot layer 105 including quantum dots 103 and an inorganic matrix material 104 is formed by epitaxial growth on an underlayer 102. In the ideal configuration of Comparative Example 1, the entire crystal structure of the quantum dot layer 105 is integrally grown by epitaxial growth without being disordered. Thus, in the inorganic matrix material 104, a discontinuous boundary surface is not generated or is less likely to be generated at which crystals are in contact with each other such that at least either crystal orientations and crystal lattices do not match each other. However, in order to fabricate the structure illustrated in FIG. 10 in Comparative Example 1, it is necessary to limit the materials of the underlayer 102, the quantum dots 103, and the inorganic matrix material 104 to a combination capable of lattice matching. In addition, it is necessary that the underlayer 102 be monocrystalline and an upper surface of the underlayer 102 be a desired crystal plane. In addition, it is necessary to slowly grow the quantum dot layer 105 so as to reduce lattice defects in the quantum dot layer 105. For example, in order to fabricate the structure illustrated in FIG. 10, a monocrystalline GaAs substrate is used as the underlayer, and a direct bandgap semiconductor such as AlInGaNP is epitaxially grown as the quantum dots 103 and the inorganic matrix material 104. This leads to low manufacturing efficiency.

As described above, the quantum dot layer Em according to the disclosure is formed by heating and cooling the coating film CF. Thus, the materials of the underlayer, the first and second quantum dots QD1 and QD2, and the inorganic matrix material Mx need not be lattice-matched.

Here, the underlayer may be any of the anode E1, the cathode E2, and the charge function layers F1 and F2. In addition, the quantum dot layer Em according to the disclosure has higher manufacturing efficiency than the quantum dot layer 105 of Comparative Example 1. Furthermore, the method according to the disclosure can form the quantum dot layer Em at low cost compared to the method requiring an epitaxial growth apparatus as in Comparative Example 1. In particular, since the method according to the disclosure can form the quantum dot layer Em at a plurality of locations at the same time, the method is suitable for a form in which the quantum dot layer Em with a large area, such as a display panel, is formed.

Comparison with Comparative Example 2

FIG. 11 is a cross-sectional view illustrating a quantum dot layer of Comparative Example 2. As illustrated in FIG. 11, a quantum dot layer 205 is formed by applying a dispersion including quantum dots 203 and a precursor of an inorganic matrix material 204 on an underlayer 202. However, since the inorganic matrix material 204 is crystalline and positions and crystal orientations of the quantum dots 203 are random, in the inorganic matrix material 204, a discontinuous boundary surface is generated where crystals are in contact with each other such that at least either the crystal orientations or the crystal lattices do not match each other. Alternatively, the boundary between the quantum dot 203 and the inorganic matrix material 204 is a discontinuous boundary surface at which crystals are in contact with each other such that at least either the crystal orientations or the crystal lattices do not match each other. At the discontinuous boundary surface and in the vicinity thereof, dangling bonds are generated at a high density, and the dangling bonds become carrier traps or non-radiative centers, so that the external quantum efficiency (EQE) of the light-emitting element according to Comparative Example 2 is reduced.

In the disclosure, as described above, at least a part of the portion of the inorganic matrix material Mx in contact with the first quantum dot QD1 is amorphous. As described above, the inorganic matrix material Mx according to the disclosure includes the halo pattern 9 at least in the electron beam diffraction image between the first quantum dot QD1 and the second quantum dot QD2. Thus, the quantum dot layer according to the disclosure reduces the discontinuous boundary surface at which crystals are in contact with each other between the portion in contact with the first quantum dot QD1 and the portion in contact with the second quantum dot QD2.

Thus, compared to the quantum dot layer 205 of Comparative Example 2, the quantum dot layer Em according to the disclosure has fewer dangling bonds, and the EQE of the light-emitting element 1 according to the disclosure is improved.

### EXAMPLE 1

The light-emitting element 1 of Example 1 according to the disclosure was fabricated such that the entire inorganic matrix material Mx was amorphous. Furthermore, the light-emitting element including the quantum dot layer 205 of Comparative Example 2 was fabricated such that the entire inorganic matrix material 204 was crystalline (more specifically, polycrystalline). In other respects, for example, materials, layer thicknesses, and carrier concentrations were made similar to each other.

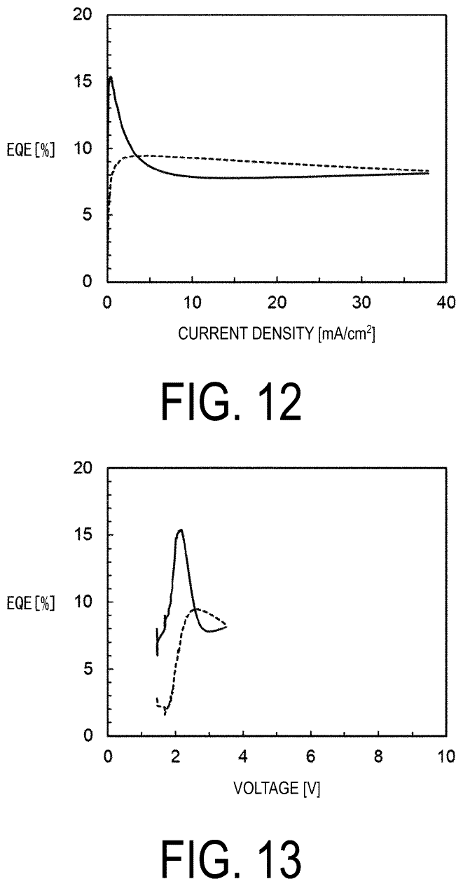

FIG. 12 is a current density-EQE graph of the light-emitting elements of Example 1 and Comparative Example 2. FIG. 13 is a voltage-EQE graph of the light-emitting elements of Example 1 and Comparative Example 2. In FIG. 12 and FIG. 13, Example 1 is indicated by a solid line, and Comparative Example 2 is indicated by a broken line. As illustrated in FIG. 12 and FIG. 13, in the light-emitting element according to Comparative Example 2, when a drive voltage was 2.5 [V] and an injection current density was 4 [mA/cm²], EQE was about 10% of the maximum value. In the light-emitting element 1 according to Example 1, when a drive voltage was 2 [V] and an injection current density was 1 [mA/cm²], EQE was about 10% of the maximum value. As compared with the light-emitting element according to Comparative Example 2, in the light-emitting element 1 according to Example 1, the drive voltage and the injection current density at which the EQE was maximized were reduced, and the maximum value of the EQE was improved. It is considered that such improvement in light-emission characteristics is caused by the configuration of the light-emitting element 1 according to Example 1 with which defects at the interface between the quantum dots QD and the inorganic matrix material Mx are reduced, the voltage when carriers are injected into the quantum dots QD is reduced, and non-emitting recombination at the defects is reduced.

### Second Embodiment

Another embodiment of the disclosure will be described below. Further, members having the same functions as those of the members described in the above-described embodiments will be denoted by the same reference numerals and signs, and the description thereof will not be repeated for the sake of convenience of description.

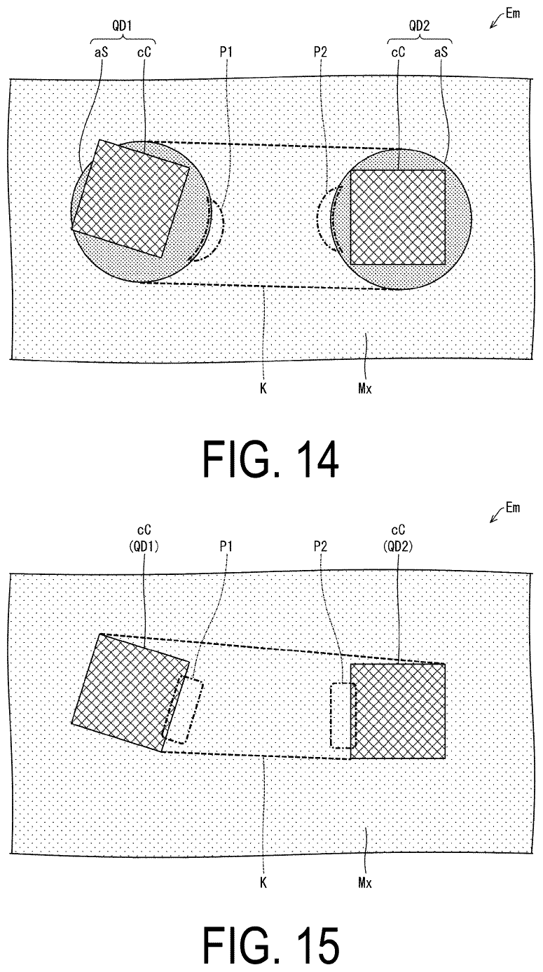

FIG. 14 is a cross-sectional view illustrating an example of a quantum dot layer according to an embodiment of the disclosure. As illustrated in FIG. 14, each of the first quantum dot QD1 and the second quantum dot QD2 according to the second embodiment has a core-shell structure including a core cC that is crystalline and a shell aS that is amorphous. The shell aS that is amorphous may be provided on a surface of the core cC. The shell aS that is amorphous may be partially formed at the surface of the core cC like the first quantum dot QD1 or may completely cover the core cC like the second quantum dot QD2. The shell aS may be made of the same material as the inorganic matrix material Mx or may be made of a different material. The shell aS may be constituted by a plurality of layers, that is, the quantum dot QD may have a multi-shell structure.

FIG. 14 does not limit the shapes and sizes of the quantum dot QD, the core cC, and the shell aS, does not limit the relationship between the core cC and the shell aS, and does not limit the crystal type of the core cC.

When the shells aS and the inorganic matrix material Mx contain the same material (same composition) and the shells aS and the inorganic matrix material Mx cannot be distinguished from each other, the concentration in the region including the shells aS and the inorganic matrix material Mx may be within a numerical range (11% or more and 91% or less, or 31% or more and 71% or less) obtained by adding the numerical range of the concentration of the shells (1% or more and 50% or less) to the numerical range of the concentration of the inorganic matrix material Mx (10% or more and 90% or less, or 30% or more and 70% or less). The percentages of the cores cC and the shells aS of the quantum dot group, and the inorganic matrix material Mx may be adjusted, as appropriate, such that the total thereof is 100% or less. As described above, when the shell aS and the inorganic matrix material Mx cannot be distinguished from each other, the shell aS may be regarded as a part of the inorganic matrix material Mx. In other words, in the above case, regardless of the structure of the quantum dot QD used at the time of manufacturing, based on observation after the manufacturing, the quantum dot QD may be regarded as a shell-less type constituted by a core, the inorganic matrix material Mx may be regarded as being in direct contact with the quantum dot QD, and the quantum dot layer Em may be regarded as including the quantum dot QD and the inorganic matrix material Mx.

When the shell aS and the inorganic matrix material Mx contain different materials, the shell aS and the inorganic matrix material Mx can be distinguished from each other by composition analysis. A composition of the portions included in the quantum dot layer can be analyzed by using any one of Secondary Ion Mass Spectrometry (SIMS), Auger Electron Spectroscopy (AES), Gas Chromatograph Mass Spectrometry (GCMS), X-ray Photoelectron Spectroscopy (XPS), and Energy Dispersive X-ray Spectroscopy (EDX), or by using any two or more thereamong in combination.

### Third Embodiment

FIG. 15 is a cross-sectional view illustrating an example of a quantum dot layer according to an embodiment of the disclosure. As illustrated in FIG. 15, each of the first quantum dot QD1 and the second quantum dot QD2 according to the third embodiment is a shell-less type constituted by the core cC. The core cC of each of the first quantum dot QD1 and the second quantum dot QD2 is in contact with the inorganic matrix material Mx.

An electron beam diffraction image of the boundary portion between the core cC of the first quantum dot QD1 and the inorganic matrix material Mx includes a bright spot group pattern and the halo pattern 9 in an overlapping manner.

FIG. 15 does not limit the shape and size of the core cC, and does not limit the crystal type of the core cC.

### Fourth Embodiment

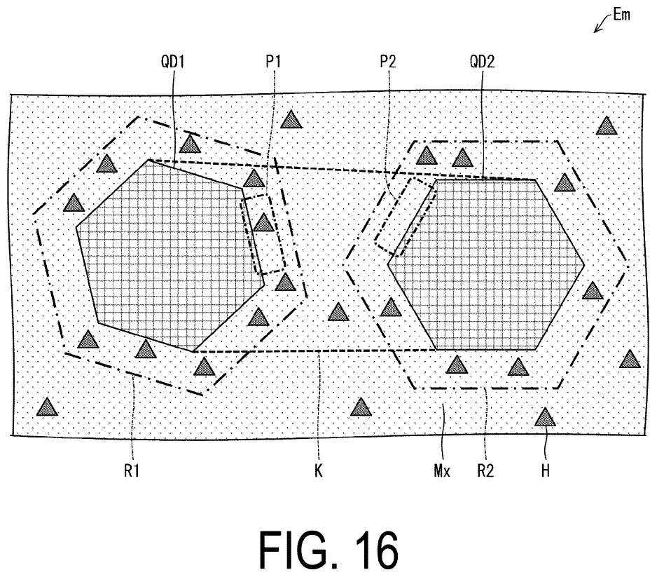

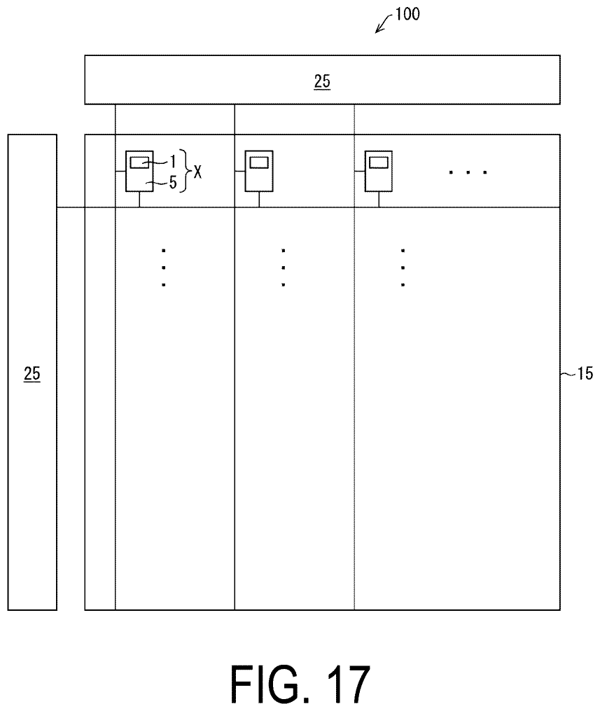

FIG. 16 is a cross-sectional view illustrating an example of a quantum dot layer according to an embodiment of the disclosure. As illustrated in FIG. 16, the inorganic matrix material Mx may contain a halogen element H. The inorganic matrix material Mx contains, as the halogen element H, one or more among fluorine (F), chlorine (CI), bromine (Br), and iodine (I).

In the portion between the first quantum dot QD and the second quantum dot QD2, that is, in a region K, the average value of a halogen element concentration in a region R1 within 1 nm from the boundary portion between the first quantum dot QD and the inorganic matrix material Mx and the average value of a halogen element concentration in a region R2 within 1 nm from the boundary portion between the second quantum dot QD and the inorganic matrix material Mx may be larger than an average value of the halogen element concentration in the other region.

An average value of the halogen element concentration in the inorganic matrix material Mx may be 10¹⁶ cm⁻³ or more and 10²⁰ cm⁻³ or less. In addition, the quantum dot QD may contain the halogen element H. The core cC may contain the halogen element H, and/or the shell cS or the shell aS may contain the halogen element H. An average value of the halogen element concentration in the quantum dot layer Em may be 10¹⁶ cm⁻³ or more and 10²⁰ cm⁻³ or less.

FIG. 16 does not limit the shapes and sizes of the first quantum dot QD1 and the second quantum dot QD2, and does not limit the relationship between the first quantum dot QD1 and the second quantum dot QD2. Each of the first quantum dot QD1 and the second quantum dot QD2 according to the fourth embodiment may be a core-shell type including the shell cS that is crystalline, a core-shell type including the shell aS that is amorphous, a multi-shell type, or a shell-less type.

By adding the halogen element H to the quantum dot dispersion DL, the inorganic matrix material Mx can contain the halogen element H. For example, fluoromethane, trifluoroacetic acid, or the like may be added to the quantum dot dispersion DL. In addition, when the material containing the halogen element H is used as the precursor J and/or the solvent S, the inorganic matrix material Mx may contain the halogen element H. For example, a metal halide such as zinc fluoride (ZnF₂) and zinc chloride (ZnCl₂) may be used as a part of the precursor J. For example, octane, or chlorobenzene may be used as the solvent S.

The halogen element H may be a ligand coordinated to the quantum dot QD in the quantum dot dispersion DL or a part of the ligand. The halogen H may capture an unpaired electron in the inorganic matrix material Mx. The constituent elements of the inorganic matrix material Mx are lost at random to generate defects in the inorganic matrix material Mx. For example, when the inorganic matrix material Mx contains group II-VI compounds, most of the deficiencies are deficiencies of group VI elements, and unpaired electrons are generated. The halogen element H captures an unpaired electron to close the shell at a site where the deficiency has occurred, leading to stabilization. As a result, the defect is stabilized, the carrier injection efficiency into the quantum dot QD is improved, and the EQE of the light-emitting element 1 is improved.

### Fifth Embodiment

FIG. 17 is a schematic view illustrating an example of a display device according to an embodiment of the disclosure. As illustrated in FIG. 17, a display device 100 according to a fifth embodiment includes a display portion 15 including a plurality of subpixels X, and a driver circuit 25 that drives the display portion 15. At least one of the subpixels X includes the light-emitting element 1 and a pixel circuit 5. The light-emitting element 1 included in the display device 100 may be the light-emitting element 1 according to any one of the first to fourth embodiments described above, or may be a light-emitting element obtained by modifying or improving the light-emitting element 1 according to any one of the first to fourth embodiments described above.

The disclosure is not limited to the embodiments described above, and various modifications may be made within the scope of the claims. Embodiments obtained by appropriately combining technical approaches disclosed in the different embodiments also fall within the technical scope of the disclosure. Furthermore, novel technical features can be formed by combining the technical approaches disclosed in each of the embodiments.

### REFERENCE SIGNS LIST

1 Light-emitting element
100 Display device
aS, cS Shell
cC Core
CF Coating film
E1 Anode
E2 Cathode
Em Quantum dot layer
H Halogen element
J Precursor
K Region
Mx Inorganic matrix material
P1 Portion (at least a part of portion in contact with first quantum dot)
P2 Portion (at least a part of portion in contact with second quantum dot)
R1 Region within 1 nm from boundary portion between first quantum dot and inorganic matrix material
R2 Region within 1 nm from boundary portion between second quantum dot and inorganic matrix material
S Solvent
QD1 First quantum dot
QD2 Second quantum dot

1. A light-emitting element comprising:
an anode and a cathode; and
a quantum dot layer positioned between the anode and the cathode, the quantum dot layer including a first quantum dot and a second quantum dot,
wherein the quantum dot layer includes an inorganic matrix material filling a space between the first quantum dot and the second quantum dot, and a portion of the inorganic matrix material in contact with the first quantum dot is at least partially amorphous.

2. A light-emitting element comprising:
an anode and a cathode; and
a quantum dot layer positioned between the anode and the cathode, the quantum dot layer including a first quantum dot and a second quantum dot,
wherein the quantum dot layer includes an inorganic matrix material filling a space between the first quantum dot and the second quantum dot, and an electron beam diffraction image of the inorganic matrix material between the first quantum dot and the second quantum dot includes a halo pattern.

3. (canceled)

4. The light-emitting element according to claim 1, wherein the first quantum dot includes a shell being crystalline.

5. The light-emitting element according to claim 4,
wherein an electron beam diffraction image of a boundary portion between the shell of the first quantum dot and the inorganic matrix material includes a bright spot group pattern and a halo pattern in an overlapping manner.

6. (canceled)

7. The light-emitting element according to claim 4,
wherein the shell of the first quantum dot and the inorganic matrix material are made of an identical material.

8. The light-emitting element according to claim 4,
wherein the shell of the first quantum dot and the inorganic matrix material are made of different materials.

9. The light-emitting element according to claim 4,
wherein a band gap of the inorganic matrix material is larger than a band gap of the shell of the first quantum dot.

10. The light-emitting element according to claim 1,
wherein each of the first quantum dot and the second quantum dot is a shell-less type constituted by a core, and
the core of the first quantum dot and the core of the second quantum dot are in contact with the inorganic matrix material.

11. (canceled)

12. The light-emitting element according to claim 1,
wherein a band gap of the inorganic matrix material is larger than a band gap of a core of the first quantum dot.

13. The light-emitting element according to claim 1,
wherein the inorganic matrix material includes one or more of a group II-VI compound, a group III-V compound, a metal oxide, and a metal sulfide.

14. The light-emitting element according to claim 1,
wherein the inorganic matrix material includes at least one of zinc sulfide, zinc oxide, and magnesium oxide.

15. The light-emitting element according to claim 13,
wherein the inorganic matrix material includes at least one of selenium and tellurium.

16. The light-emitting element according to claim 1,
wherein the inorganic matrix material includes a halogen-element.

17. The light-emitting element according to claim 16,
wherein in a portion between the first quantum dot and the second quantum dot, an average value of a halogen concentration in a region within 1 nm from a boundary portion between the first quantum dot and the inorganic matrix material and an average value of a halogen concentration in a region within 1 nm from a boundary portion between the second quantum dot and the inorganic matrix material are larger than an average value of a halogen concentration in the other region.

18. The light-emitting element according to claim 16 wherein an average value of a halogen concentration in the quantum dot layer or the inorganic matrix material is 10¹⁶ cm⁻³ or more and 10²⁰ cm⁻³ or less.

19. The light-emitting element according to claim 16,
wherein the inorganic matrix material includes one or more among fluorine, chlorine, bromine, and iodine as the halogen

20. The light-emitting element according to claim 1,
wherein a layer thickness of the quantum dot layer is from 10 to 50 [nm].

21. The light-emitting element according to claim 1,
wherein the quantum dot layer includes a plurality of quantum dots including the first quantum dot and the second quantum dot, and
a quantum dot density in the quantum dot layer is from 1×10¹⁷ to 6×10¹⁷ [cm⁻³].

22. The light-emitting element according to claim 1,
wherein the quantum dot layer includes a plurality of quantum dots including the first quantum dot and the second quantum dot, and
an average particle diameter of the plurality of quantum dots is from 5 to 50 [nm].

23. (canceled)

24. A light-emitting element manufacturing method comprising:
forming a coating film including a first quantum dot, a second quantum dot, a precursor of a group II-VI compound, and a solvent; and
heating the coating film, thus causing the precursor to be modified into the group II-VI compound, and then cooling the coating film at a rate equal to or more than 100 degrees Celsius/second.
